(19) United States
(12) Patent Application Publication
(10) Pub. No.: US 2009/0162170 A1
(43) Pub. Date: Jun. 25, 2009

(54) TANDEM TYPE SEMICONDUCTOR-PROCESSING APPARATUS

(75) Inventors: Takayuki Yamagishi, Tokyo (JP); Hiroki Kanayama, Tokyo (JP); Noboru Shigeyama, Tokyo (JP); Hideaki Fukuda, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/960,252

(22) Filed: Dec. 19, 2007

(51) Int. Cl. H01L 21/677

(52) U.S. Cl. 414/217; 901/2

(57) ABSTRACT

A tandem type semiconductor-processing apparatus includes: a processing section including multiple units arranged in tandem, each of which unit includes a reaction chamber and a load lock chamber with an load lock interface; a FOUP section including at least one FOUP having a wafer cassette and a front opening interface; and a mini-environment section having a single interior connected to the processing section via each load lock interface on one side of the mini-environment section and connected to the FOUP section via each front opening interface on another side of the mini-environment section opposite to the one side.

### BACKGROUND OF THE INVENTION

1. Field of the Invention

The present invention relates to a semiconductor manufacturing apparatus of vacuum load lock type. It also relates to a structure and operating method of a compact sheet-feed semiconductor apparatus capable of processing wafers efficiently and continuously or simultaneously.

2. Description of the Related Art

In general, conventional semiconductor manufacturing apparatuses of vacuum load lock type, which are used in the manufacture of integrated semiconductor circuits, comprise a load lock chamber, transfer chamber and multiple reaction chambers (processing chambers) connected to the transfer chamber. Each chamber uses a wafer transfer robot to automatically feed wafers, and is operated as follows. First, an atmospheric robot installed in a mini-environment carries a wafer into the load lock chamber from a wafer cassette or FOUP (a box equipped with removable wafer cassettes and front-opening interface). Next, the load lock chamber is evacuated to a vacuum state, after which a vacuum robot inside the common polygonal transfer chamber is used to transfer the wafer to each reaction chamber. Once the wafer has been processed in the reaction chamber, the wafer is transferred to the load lock chamber via the vacuum robot. Finally, the interior of the load lock chamber is restored to atmosphere and the processed wafer is carried out to a cassette or FOUP via the atmospheric robot. This type of apparatus is generally called a “cluster tool.” However, an attempt to configure a “cluster tool” apparatus offering higher productivity (throughput) will increase the installation space and width (faceprint) of the apparatus.

In the meantime, apparatuses have been developed where the load lock chamber is equipped with a transfer mechanism, and reaction chambers are provided adjoining the load lock chamber via a gate valve (GV) in order to reduce the footprint of the apparatus. However, this configuration also presents the same problem; i.e., increasing the number of reaction chambers to configure an apparatus offering higher throughput will still increase the installation space and faceprint of the apparatus. Also, the number of reactors that can be handled by one atmospheric robot is limited, and therefore an increase in the number of reaction chambers necessitates the numbers of atmospheric robots, FOUP openers, etc., to be increased accordingly.

### SUMMARY OF THE INVENTION

In an embodiment of the present invention aimed at solving at least one of the problems mentioned above, a semiconductor manufacturing apparatus of vacuum load lock type is provided wherein said semiconductor manufacturing apparatus is characterized in that it comprises a load lock chamber, a reaction chamber adjoining the load lock chamber, and an atmospheric transfer robot installed outside the load lock chamber, where the load lock chamber has a wafer transfer mechanism that can be operated in vacuum and the chamber structure that allows wafers to be exchanged between the atmospheric transfer robot and each chamber is stacked vertically over at least two levels.

In another embodiment, a semiconductor manufacturing apparatus according to the embodiment described above is provided, wherein said semiconductor manufacturing apparatus is characterized in that a FOUP stocker with at least one FOUP (a box equipped with removable wafer cassettes and front-opening interface) opener is provided in front of the atmospheric transfer robot so that multiple FOUPs can be carried in/stored and set/carried out temporarily, and therefore wafers can be exchanged between the FOUP stocker and atmospheric transfer robot.

In another embodiment, a semiconductor manufacturing apparatus according to either of the embodiments described above is provided, wherein said semiconductor manufacturing apparatus is characterized in that at least two pairs of load lock chamber and reaction chamber are installed in the horizontal direction, and a FOUP stocker with at least two FOUP openers capable of storing multiple FOUPs temporarily is provided in front of the atmospheric transfer robot so that wafers can be exchanged between the FOUP stocker and atmospheric transfer robot.

In yet another embodiment, a semiconductor manufacturing apparatus according to any one of the embodiments described above is provided, wherein said semiconductor manufacturing apparatus is characterized in that the atmospheric transfer robot comprises at least two robots having a single wafer transfer arm or one robot having at least two wafer transfer arms, and at least two wafers are carried out of the FOUP almost simultaneously and installed in the wafer transfer mechanism inside the load lock chamber almost simultaneously.

For purposes of summuarizing the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIGS. 1A-1C are schematic diagrams of a base structure of a plasma CVD apparatus usable for an embodiment of the present invention. FIGS. 1A-1C are top view, side view, and perspective view, respectively.

FIGS. 2A-2C are schematic diagrams of a tandem type plasma CVD apparatus according to an embodiment of the present invention. FIGS. 2A-2C are top view, side view, and perspective view, respectively.

FIGS. 3A-3C are schematic diagrams of two tandem type plasma CVD apparatuses placed side by side according to an embodiment of the present invention. FIGS. 3A-3C are top view, side view, and perspective view, respectively.

FIGS. 4A-4B are schematic diagrams of a tandem type plasma CVD apparatus using a FOUP stocker according to an embodiment of the present invention. FIGS. 4A-4B are side view and perspective view, respectively.

FIGS. 5A-5B are schematic diagrams of a tandem type plasma CVD apparatus using two atmospheric robots according to an embodiment of the present invention. FIGS. 5A-5B show movement of the atmospheric robots.

### DETAILED DESCRIPTION OF THE PREFERRED EMBODIMENT

The present invention will be explained in detail with reference to preferred embodiments. However, the preferred embodiments are not intended to limit the present invention.

The semiconductor manufacturing apparatus and method proposed by the present invention are explained by referring to the drawings.

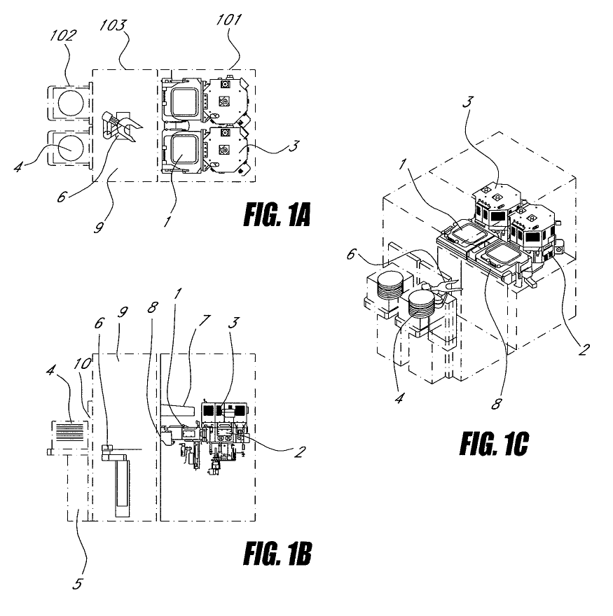

Examples of the semiconductor manufacturing apparatus pertaining to the present invention is explained. FIGS. 1A through 1C show an example of the basic structure of a semiconductor manufacturing apparatus prior to the vertical type that can be used in an example of the present invention. This apparatus comprises a process section 101, FOUP section 102 and mini-environment section 103, where the process section 101 stores a modular apparatus that integrates in the horizontal direction two numbers of a unit comprising a load lock chamber 1, transfer chamber 2 and reaction chamber 3. For your information, the load lock chamber 1 is equipped with a wafer transfer unit, and wafers are carried in and out between the transfer chamber 2 and load lock chamber 1. The reaction chamber 3 is installed above the transfer chamber 2. The load lock chamber 1 is connected to the mini-environment section 103 via a gate valve 8. In other words, the gate valve 8 functions as a load lock chamber interface. Additionally, the process section 101 is equipped with a cooling stage 7 above the load lock chamber 1 so that the high-temperature wafer that has been carried out of the load lock chamber 7 can be temporarily stored and cooled.

The mini-environment section 103 has a single interior space 9 in which an atmospheric robot 6 is placed to carry in/out wafers between the FOUP section 102 and process section 101. The FOUP section 102 has a wafer cassette 4 with a FOUP opener 5, and the FOUP opener 5 functions as an open front interface 10. The atmospheric robot 6 can be moved horizontally between the two wafer cassettes 4 and two load lock chambers 1. Although the robot can also move vertically between the load lock chamber 1 and cooling stage 1 to move vertically over the wafer cassette, the robot cannot move any further in the vertical direction (the drive part itself does not move in the vertical direction).

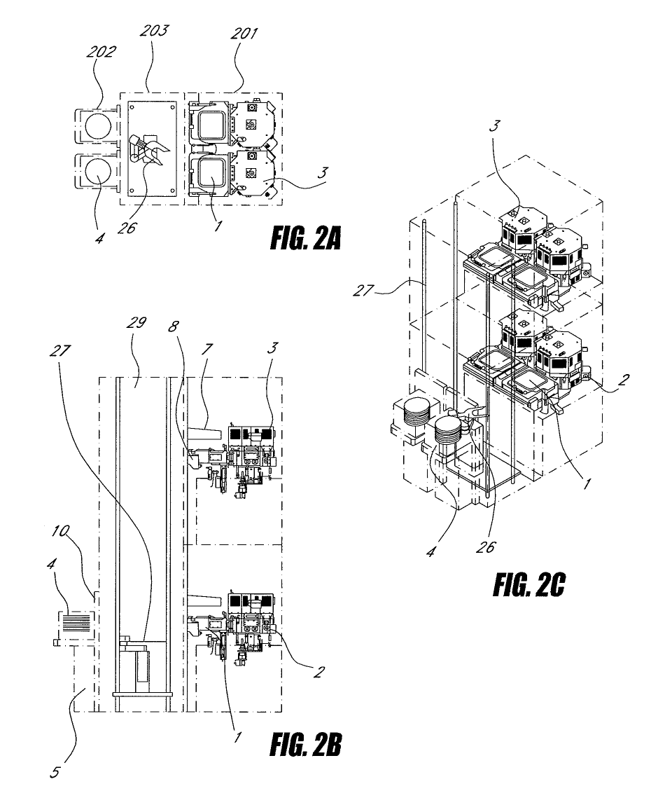

FIGS. 2A through 2C show an apparatus that has the same footprint as the apparatus illustrated in FIGS. 1A through 1C but offers double the productivity by stacking load lock chambers 1, transfer chambers 2 and reaction chambers 3 over two levels on top of each other. In the figures, two modules are stacked vertically for the process section 201. However, the height of this process section 201 is not twice the height of the process section 101 shown earlier, and in fact this process section can be structured with sixty to eighty percent of the height of 101. An atmospheric robot 26 is installed in the single interior space 29 provided in the mini-environment section 203, where this atmospheric robot 26 can move in the vertical direction to carry in/out wafers to/from the two modules installed vertically and the FOUP opener 5 and wafer cassette 4 in the FOUP section 202. In this case, the atmospheric robot 26 moves up and down using the four slide rails 27 as the pillars. Other horizontal movements, as well as the movement between the cooling stage 7 and load lock chamber 1 and vertical movement over the wafer cassette 4, are the same as the corresponding functions of the atmospheric robot 6 shown in FIG. 1.

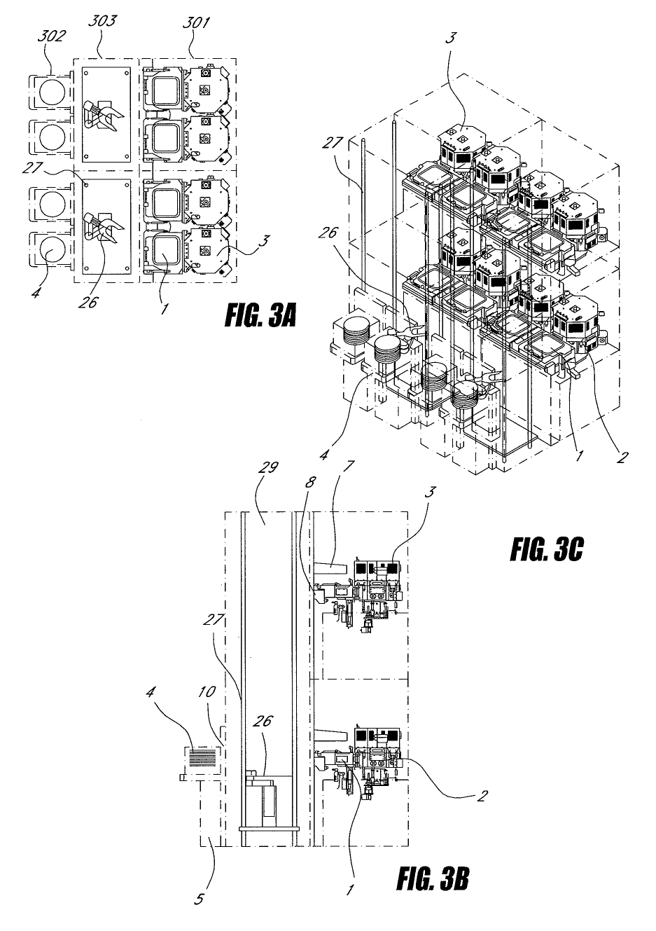

FIGS. 3A through 3C show an apparatus where multiple units of the apparatus illustrated in FIGS. 2A through 2C are installed side by side to further increase productivity. Here, two modules are installed vertically and also horizontally in the process section 301, and the mini-environment section 303 has two atmospheric robots 26 while the FOUP section 302 has four wafer cassettes 4 and four FOUP openers 5. In this figure, multiple units of the apparatus shown in FIGS. 2A through 2C are placed independently and side by side, where each space 29 in the mini-environment section 303 remains independent. Depending on the embodiment, however, the two spaces 29 may be used in common to operate a common atmospheric robot to handle the four modules. In this case, the FOUP section 302 may be able to have two FOUP openers 5 and two wafer cassettes 4.

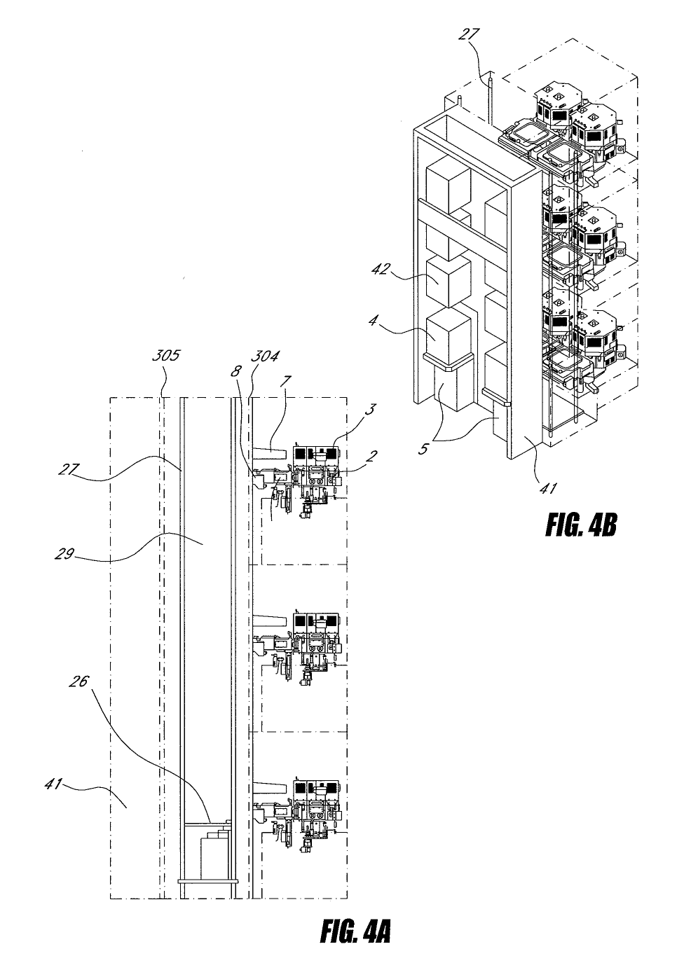

FIGS. 4A and 4B show an optimal example of the present invention. Multiple units, each comprising a pair of load lock chambers 1, transfer chambers 2 and reaction chambers 3 placed in the horizontal direction, are stacked vertically over three levels to triple the productivity. A cassette (FOUP) stocker 41 is provided in the FOUP section 402 to speed up the feed of the wafer cassette (FOUP) 4. It should be noted that the height of the process section 301 is significantly lower than three times the height of the process section 101 shown in FIGS. 1A through 1C, where the specific height is only fifty to seventy percent. In the mini-environment 303, the atmospheric robot 26 in the single space 29 moves to levels higher than the apparatus shown in FIGS. 2A through 2C, which explains the higher position of the slide rail 27. As evident from FIGS. 2A through 2C, by elongating the mini-environment section 303 this way (the height of the mini-environment section is greater than its width), airflows in the space 29 inside the mini-environment section 303 can be controlled more uniformly and efficiently. This configuration is also efficient in that the travel distance of the atmospheric robot 26 can be shortened compared to the horizontal layout.

For your reference, six buffer storage 42 units are installed in the FOUP stocker 41 to feed wafer cassettes 4.

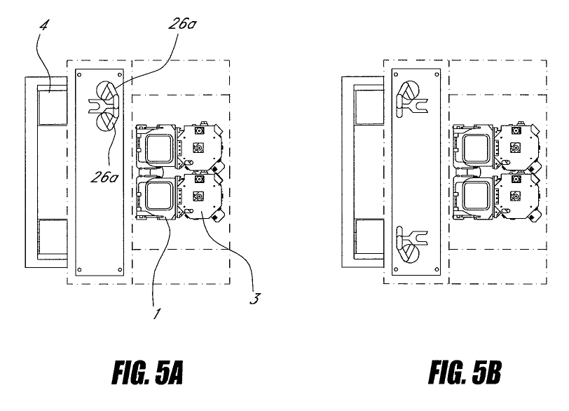

FIGS. 5A and 5B show plan views of FIGS. 4A and 4B, where two atmospheric robots 26a, 26b are placed. The six reaction chambers 3 offer high wafer processing capability and if the process time is short, the throughput per hour is generally 40 wafers per hour per RC, which corresponds to a processing speed of 240 wafers per hour per system. To achieve 240 wafers per hour, the atmospheric robot must repeat carry in/out actions between the FOUP (wafer cassette) and load lock chamber at a speed of four wafers per minute, which is impossible for a single atmospheric transfer robot to achieve. Accordingly, two sets of atmospheric transfer robots are placed in the mini-environment section. This way, each robot should only repeat carry in/out actions simultaneously at a speed of two wafers per minute per arm between the FOUP and load lock chamber. Alternatively, it may also be effective to install a single atmospheric transfer robot equipped with two transfer arms so that two wafers can be transferred simultaneously.

FIG. 5A shows the condition immediately before the atmospheric transfer robot picks up each new wafer from the FOUP or immediately after the robot has transferred a processed wafer to the FOUP. FIG. 5B shows the condition immediately before the atmospheric transfer robot picks up each processed wafer from the load lock chamber or immediately after the robot has transferred an unprocessed wafer to the load lock chamber.

If there is only one FOUP opener, the atmospheric robot stands by while the FOUPs are changed after the completion of wafer processing, until the changeover operation is completed, and this reduces the throughput. It would be efficient to provide at least two FOUP openers, because processing of wafers in the second FOUP can be started without delay once the processing of wafers in the first FOUP has completed.

The speed of 240 wafers per hour corresponds to 9.6 FOUPs per hour, which requires a FOUP to be fed and carried out every 6.25 minutes. However, the FOUP feed rate is unstable on actual production lines, and therefore an ingenuous solution is required. If the processing speed of the manufacturing apparatus is very high, for example, FOUPs cannot be fed fast enough and the FOUP feed rate may have to be limited. To resolve this problem, a FOUP stocker 41 capable of temporarily storing multiple FOUPs is equipped in the apparatus shown in FIGS. 5A and 5B.

For your information, the atmospheric robot is installed on XY slide-rails 27 and controlled automatically in order to widen the moving range of the robot itself to allow wafers to be placed in/taken out of the load lock chambers provided horizontally and vertically.

Table 1 compares two apparatus configurations having the same throughput, one comprising three units of the conventional apparatus illustrated in FIGS. 1A through 1C, and the other comprising one apparatus shown in FIG. 4.

TABLE 1

| | | FOUP | FOUP | Mini- | Atmospheric | Throughput | Cost | Footprint | Faceprint |
|---|---|---|---|---|---|---|---|---|---|
| | | stocker | opener | environment | robot | (WPH) | (KJPY) | (constant) | (constant) |
| FIG. 1-3 | Unit price | 0 | 1,200 | 1,100 | 2,500 | | | 10 | 10 |
| units | Required | 0 | 6 | 3 | 3 | | | 3 | 3 |
| | number of units | | | | | | | | |
| | | 0 | 7,200 | 3,300 | 7,500 | 240 | 18,000 | 30 | 30 |
| FIG. 4-1 | Unit price | 5,000 | 0 | 1,100 | 3,000 | | | 12 | 12 |
| units | Required | 1 | 2 | 1 | 2 | | | 1 | 1 |
| | number of units | | | | | | | | |
| | | 5,000 | 0 | 1,100 | 6,000 | 240 | 12,100 | 12 | 12 |
| | Improvement (%) | | | | | | (33) | (60) | (60) |

*The footprint/faceprint is indicated by a constant (the value applicable to one unit of the apparatus shown in FIG. 1 is assumed as 10) excluding maintenance space.

As shown by Table 1, the apparatus according to the present invention achieves the same throughput at approx. 33% less cost and approx. 60% less footprint and faceprint.

Next, the process sequences of the apparatuses shown in FIGS. 1A through 1C and FIGS. 4A and 4B are explained. Here, a timing chart with a deposition time of 75 seconds and a sequence of 5 depositions+1 cleaning is assumed. Wafers in the reaction chamber are changed using a wafer transfer unit equipped with dual-blade end effectors on its LL arm, where the wafer transfer unit is of the type that allows the applicable wafers to be loaded/unloaded in a single action (e.g., the systems disclosed in U.S. Pat. No. 6,860,711, U.S. Patent Publication No. 2006/0113806, and U.S. patent application Ser. No. 11/512,637 owned by the same assignee as in the present application, the disclosure of which is herein incorporated by reference in their entirety). The LLC and atmospheric transfer robot needs to perform backfill of the LLC, load a wafer before deposition from “FOUP to LLC,” unload the wafer completing deposition from “LLC to cleaning stage,” evacuate the LLC, and collect the wafer on the cooling stage from “cooling stage to FOUP,” during 85 seconds including a deposition time of 75 seconds and 10 seconds for changing wafers in the reaction chamber.

Next, the process sequence of the apparatus shown in FIGS. 4A and 4B (FIGS. 5A and 5B) is explained. The same conditions described above apply here, and main modules (each comprising a cooling stage, load lock chamber and reaction chamber) are stacked over three levels.

Since a FOUP needs to be input every 285 seconds (4 minutes 45 seconds), a FOUP stocker is required for this apparatus in practical operation. The FOUP stocker may preferably be RICSS300 made by Rorze or equivalent. There are six FOUP buffer storage units to support OHT.

Two atmospheric transfer robots are installed, and each robot has an independent right-left slide axis so that wafers can be transferred out of the FOUP and placed in the LLC, or vice versa, simultaneously on the right and left sides. Also, there is a vertical slide axis to cover three vertical levels.

The sequence is explained according to the flow of wafers.

[1]The automatic FOUP transfer system places the first FOUP (hereinafter referred to as “F1”) in the FOUP stocker on the apparatus side.

[2] The FOUP stocker sets the FOUP in load port 1. Specifically, every time a wafer is transferred by each atmospheric robot from the FOUP to the load lock chamber, the total number of wafers decreases by 2 from 25. Also, with each transfer by each atmospheric robot of a wafer that has been cooled to normal temperature (temperature at which the wafer can be stored in the FOUP) on the cooling stage, the total number of wafers increases by 2.

The second FOUP (hereinafter referred to as “F2”) is placed within 285 seconds (4 minutes 45 seconds). In reality, however, it is not practical to feed FOUPs at a cycle of less than 5 minutes, and thus a FOUP stocker needs to be installed to mitigate the FOUP placement cycle.

[3] The front end indicates the time required by atmospheric robots 1 and 2 to place wafers on the end effectors. To be specific, atmospheric robot 1 transfers wafer B1 (a wafer before deposition is indicated by B, followed by a sequential value) from F1 and places it in load lock chamber 1, while atmospheric robot 2 simultaneously places wafer B2 in load lock chamber 2. The time required for the placements is 10 seconds.

[4] There are first, second and third levels of main modules, where each module has one set of load lock chambers capable of storing two wafers, one set of load lock pumps, and two sets of reaction chambers.

To be specific, wafer B1 is placed in load lock chamber 1, and wafer B2 is placed in load lock chamber 2, after which the load lock chambers are evacuated. The evacuation time is 10 seconds.

After the evacuation, the wafers are placed in the reaction chambers. The wafer changeover time is 10 seconds.

After the wafers have been changed, deposition is started simultaneously in reaction chambers 1 and 2 (the deposition time is assumed as 75 seconds). The load lock chambers are opened to atmosphere while deposition is in progress in the reaction chambers, and the next pre-deposition wafers B7/B8 are placed and the load lock chambers are evacuated.

After films have been deposited on the wafers, the wafers are changed. Wafers B7/B8 are transferred from the load lock chambers and placed in the reaction chambers, while wafers A1/A2 (a wafer completing deposition is indicated by A, followed by a sequential value) are transferred from the reaction chambers and placed in the load lock chambers.

Once a wafer has been transferred and placed, deposition is started in each reaction chamber.

When the load lock chambers are opened to atmosphere, wafers B13/B14 are transferred from F1 and placed, while wafers A1/A2 are placed on the cooling stages. At this time, the atmospheric robots pick up wafers B13/B14 from F1 upon start of opening of the load lock chambers as a trigger, after which the robots stand by in front of the load lock chambers. This reduces the wafer placement time to 5 seconds after the opening of the load lock chamber to atmosphere (normally it takes 10 seconds). The atmospheric robots move wafers A1/A2 to the cooling stages immediately after placing wafers B13/B14 in the load lock chambers, which also reduces the wafer placement time to 5 seconds (normally it takes 10 seconds).

As for wafer placement from the cooling stage to FOUP, this placement is performed after the next wafer completing deposition has been placed on the cooling stage, because the cooling time normally is set to 60 seconds. In this example, wafers Z1/Z2 are returned from cooling stages 1 and 2 to F1 after A7/A8 have been placed on the cooling stages.

The above processing is repeated, which requires that the reaction chambers be cleaned after several deposition cycles. In this example, one cleaning is assumed after five deposition cycles (5D1C). In other words, the reaction chambers are cleaned after A25/A26 have been collected into the load lock chambers.

The above methods allow the atmospheric transfer robots to place wafers without having their transfer speeds limited, and this configuration comprising two atmospheric robots, two FOUP openers and one mini-environment can achieve three times the running throughput of the apparatus shown in FIG. 1. By the multi-level apparatus configuration explained above, a semiconductor manufacturing apparatus and method, ensuring small footprint, small faceprint and low cost, can be achieved.

In the present disclosure where conditions and/or structures are not specified, the skilled artisan in the art can readily provide such conditions and/or structures, in view of the present disclosure, as a matter of routine experimentation. For example, the system disclosed in U.S. Pat. No. 6,630,053 can be used when practicing an embodiment of the present invention, the disclosure of which is herein incorporated by reference it its entirety.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A tandem type semiconductor-processing apparatus comprising:
a processing section comprising multiple units arranged in tandem, each unit comprising a reaction chamber, a transfer chamber, and a load lock chamber with a load lock interface, wherein the reaction chamber is disposed on top of the transfer chamber, the load lock chamber is disposed beside the transfer chamber and includes an arm laterally movable between the load lock chamber and the transfer chamber, said arm being provided with upper and lower end-effectors at its distal end, wherein one unit is arranged on top of another unit, and the load lock interfaces of the units face in the same direction, each of the transfer chambers and reaction chambers being alternately arranged in a vertical direction;
an FOUP (front opening unified pod) section comprising at least one FOUP having a wafer cassette and a front opening interface; and
a mini-environment section connected to the processing section via each load lock interface on one side of the mini-environment section and connected to the FOUP section via each front opening interface on another side of the mini-environment section opposite to the one side, said mini-environment section comprising at least one atmospheric robot for transferring a wafer between the processing section and the FOUP section via each load lock interface and each front opening interface, wherein each load lock interface and each front opening interface are connected to a single interior of the mini-environment section where the at least one atmospheric robot is movable vertically to reach the load lock interfaces disposed in tandem,
wherein each unit further comprises a cooling stage disposed above the load lock chamber for temporarily placing a wafer for cooling, said cooling stage being open to the interior of the mini-environment, each of the cooling stages and load lock interfaces being alternately arranged in a vertical direction.

2. The tandem type semiconductor-processing apparatus according to claim 1, wherein the at least one FOUP is two or more FOUPS.

3. The tandem type semiconductor-processing apparatus according to claim 1, wherein the FOUP section further comprises multiple buffer storages which are replaceable with the wafer cassette of each FOUP.

4. The tandem type semiconductor-processing apparatus according to claim 1, wherein two units arranged side by side constitute a module, and multiple modules are arranged in tandem, wherein the at least one atmospheric robot is movable horizontally and vertically to reach the load lock interfaces disposed in tandem and side by side.

5. The tandem type semiconductor-processing apparatus according to claim 4, wherein the at least one atmospheric robot is two atmospheric robots or one atmospheric robot with two independently movable arms, wherein the two atmospheric robots or the two independently movable arms are synchronized.

6. The tandem type semiconductor-processing apparatus according to claim 5, wherein the two atmospheric robots or the two independently movable arms simultaneously transfer two wafers from the FOUP section through the front opening interface to the processing section through the load lock interfaces arranged side by side.

7. The tandem type semiconductor-processing apparatus according to claim 1, wherein the mini-environment section has a height, width, and depth as viewed facing the load lock interfaces, wherein the height is greater than the width.

8. The tandem type semiconductor-processing apparatus according to claim 1, wherein the number of the units is greater than the number of the FOUPS.

9. The tandem type semiconductor-processing apparatus according to claim 1, wherein in the single interior of the mini-environment section, air blows in a downward direction.

10. (canceled)

11. The tandem type semiconductor-processing apparatus according to claim 1, wherein the reaction chamber and transfer chamber are provided with a buffer mechanism for buffering a substrate while exchanging substrates in the reaction chamber and transfer chamber.
